(19) United States
(12) Patent Application Publication
(10) Pub. No.: US 2025/0014642 A1
(43) Pub. Date: Jan. 9, 2025

(54) Data Storage System Using a Light Valve System

(71) Applicant: Seurat Technologies, Inc., Wilmington, MA (US)

(72) Inventors: Francis L. Leard, Sundbury, MA (US); James A. DeMuth, Woburn, MA (US); Andrew J. Bayramian, Marblehead, MA (US)

(21) Appl. No.: 18/762,131

(22) Filed: Jul. 2, 2024

Related U.S. Application Data
(60) Provisional application No. 63/512,187, filed on Jul. 6, 2023.

(51) Int. Cl. G11C 13/04

(52) U.S. Cl. CPC G11C 13/048

(57) ABSTRACT

A data storage system includes a high-power laser to form a laser beam at a first wavelength. A 2D patternable light valve having a phase change material responsive to a write beam at a second wavelength, and non-responsive at the first wavelength is used to pattern the laser beam.

### RELATED APPLICATION

The present disclosure is part of a non-provisional patent application claiming the priority benefit of U.S. Patent Application No. 63/512,187, filed on Jul. 6, 2023, which is hereby incorporated by reference in its entirety.

### TECHNICAL FIELD

The present disclosure generally relates to data storage systems that operate with two-dimensional light valve systems. More particularly, use of phase change materials differently responsive at different wavelengths are used to enable respective data write and read beams.

### BACKGROUND

Lasers have long been used as components of data storage systems that support random access memory (RAM) or read only archival memory (ROM). Materials that can be used for data storage include GaTe and GeSbTe (chalcogenide glasses), which can form a part of a phase change random access memory (PRAM). Such glasses can support data write and read through an entire volume, rather than a surface of the glass. Bulk storing of data is also possible in optically non-photosensitive transparent materials such as fused quartz, which advantageously has high chemical stability and resistance. A fused glass storage media can store and read data using material supported changes that result in intensity, polarization, and wavelength changes to modulate data.

Currently, phase change or material defect modification used for optical memory are serially written along one or more one dimensional lines through a volume of a data storage media. Petabytes or more of data can be stored in relatively small volumes. Unfortunately, writing and reading such large amounts of data can result in unusably long write/read/access of pages within a volume media

### BRIEF DESCRIPTION OF THE DRAWINGS

Non-limiting and non-exhaustive embodiments of the present disclosure are described with reference to the following figures, wherein like reference numerals refer to like parts throughout the various figures unless otherwise specified.

FIG. 1A illustrates use of phase change cooling within a light valve structure;

FIG. 1B illustrates a volumetric phase change light valve.

FIG. 1C illustrates a quantum dot phase change light valve;

FIG. 1D illustrates metamaterial phase change light valve;

FIG. 1E illustrates a pixel strained phase change light valve.

FIG. 1F illustrates a structured material strain phase change light valve;

FIG. 1G illustrates a non-linear material phase change light valve;

FIG. 1H illustrates a use of a phase change light valve in an adaptive optical structure;

FIG. 2 illustrates a block diagram of a light valve based data storage system supporting a beam dump, a phase change light valve, and a heat engine;

FIG. 3 illustrates a phase change light valve based data storage system; and

FIG. 4 illustrates another embodiment of a method for providing phase change light valve data storage.

### DETAILED DESCRIPTION

In the following description, reference is made to the accompanying drawings that form a part thereof, and in which is shown by way of illustrating specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The following detailed description is, therefore, not to be taken in a limiting sense.

In the following disclosure, a data storage system includes a high-power laser to form a laser beam at a first wavelength. A 2D patternable light valve having a phase change material responsive to a write beam at a second wavelength, and non-responsive at the first wavelength is used to pattern the laser beam.

In some embodiments, the phase change material supports volumetric phase change.

In some embodiments, the phase change material is a quantum dot phase change material.

In some embodiments, the phase change material is a pixel strained phase change material.

In some embodiments, the phase change material is a structured material.

In some embodiments, the phase change material is a non-linear material phase change material.

Light valve (LV) technology can be limited in ability to switch pixel speeds due to its reliance on photoconductors and liquid crystal materials. Some current devices make use of group phenomena such as accumulation of charge across a photoconductor (e.g. the accumulation of polarization retardation across a liquid crystal cell). A phase change-based system can locally modify the state of the material to undergo a phase change from one state (crystalline) to another (amorphous) and in doing so modifies its response to light (reflection/transmission, polarization, phase, amplitude or wavelength). The resulting effect of phase change LVs is robustness in the presence of light, speed and/or added functionality.

Advantageously, phase change LVs do not require photoconductors or transparent conductive oxides (two structures within standard LVs that are failure prone) but rely instead on the molecular rearrangement from one state of material to another through the direct action of the write beam. Once the state change occurs (e.g. crystalline to amorphous), the material is stable with no modifying influences afforded by the light on the affected volume. The affected volume has a different influence on the beam with respect to those volumes that were not changed by the write beam. Additionally, by adjusting the intensity levels of the write beam, stress between the pixels and/or voxels in the affected volume can be actively adjusted so that different aspects (its polarization, phase, reflection, refraction, wavelength response) of the beam can be modified. In some variations of phase change LVs, the switching speed by which the beam can be modified is orders of magnitude faster than what is currently available in current LVs.

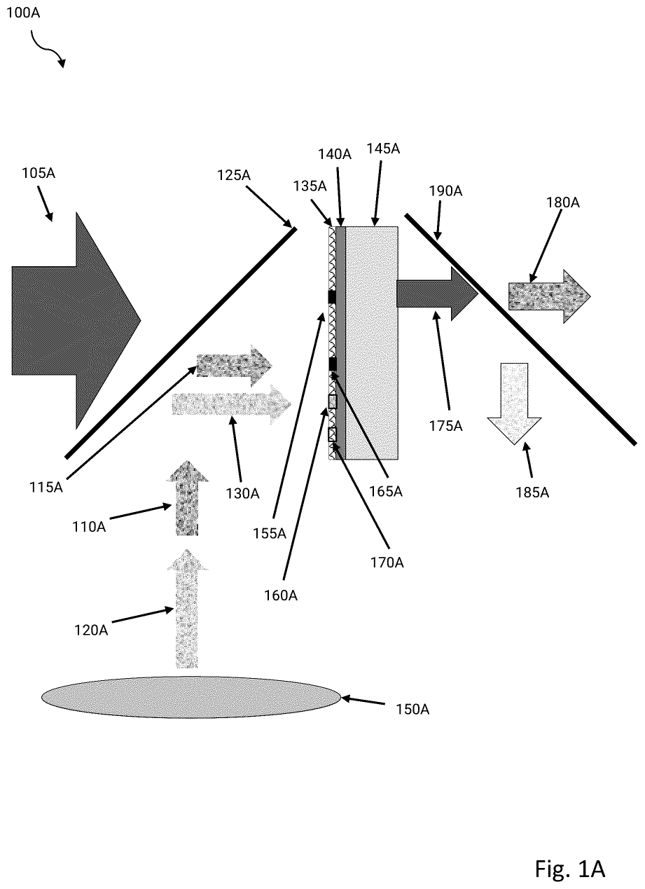

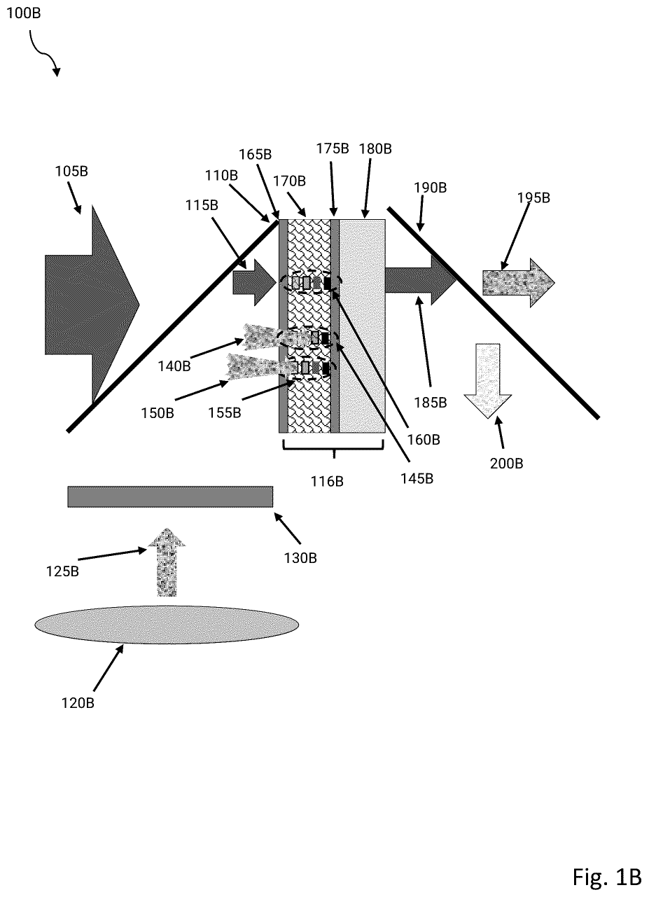

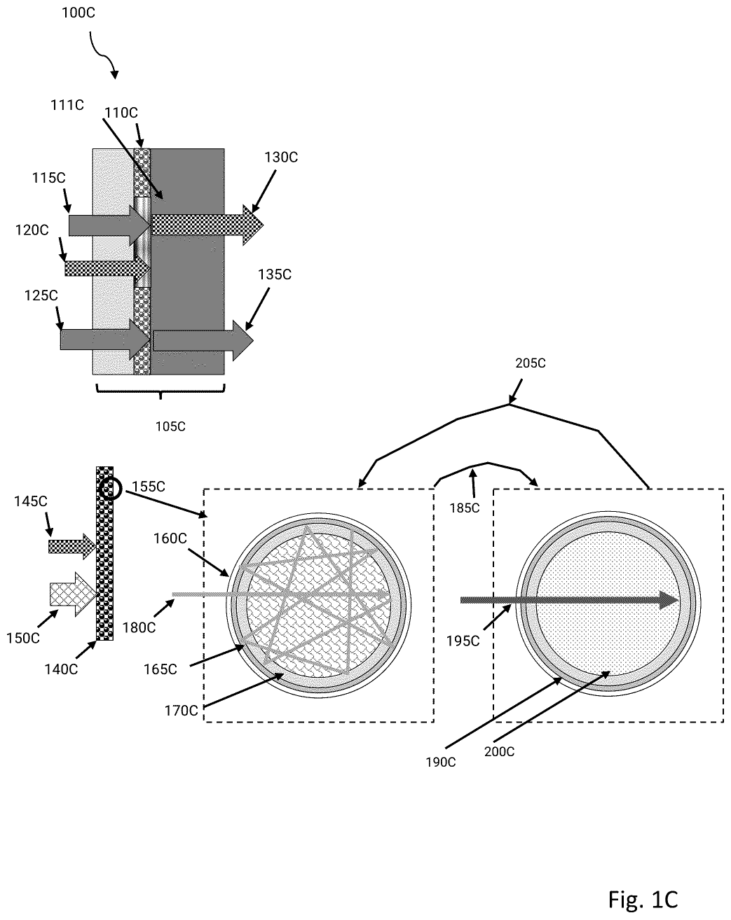

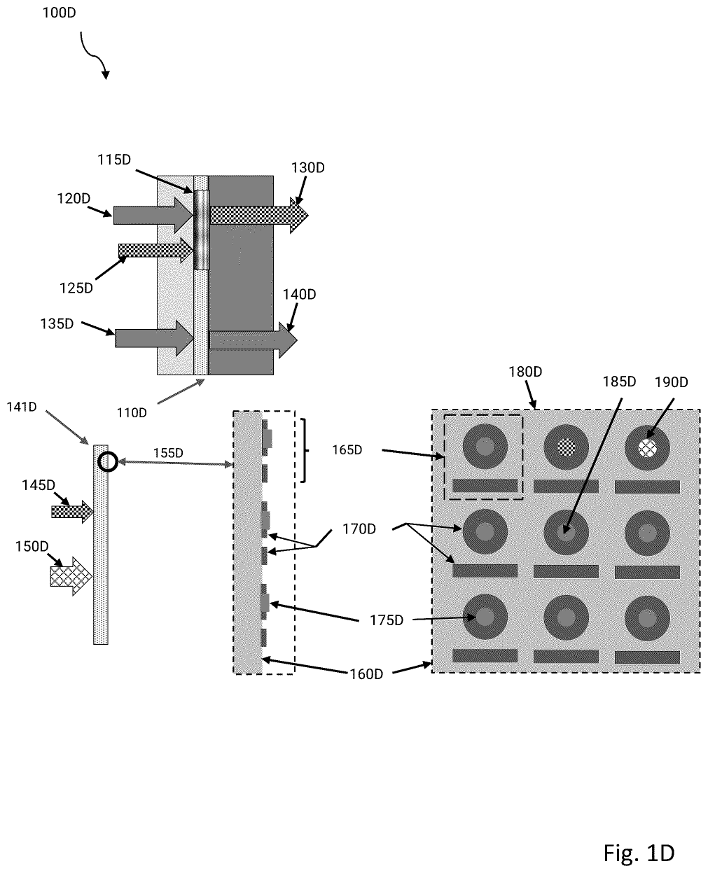

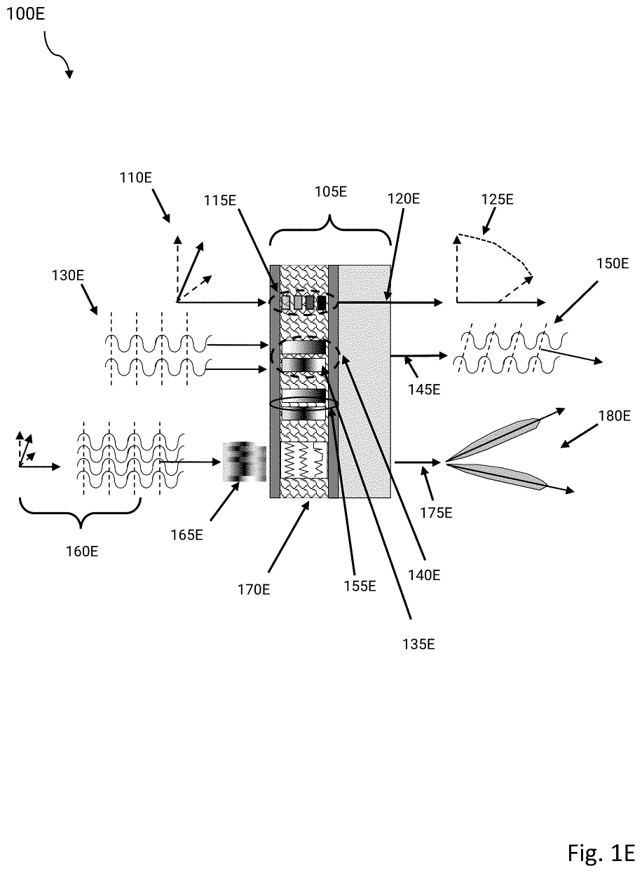

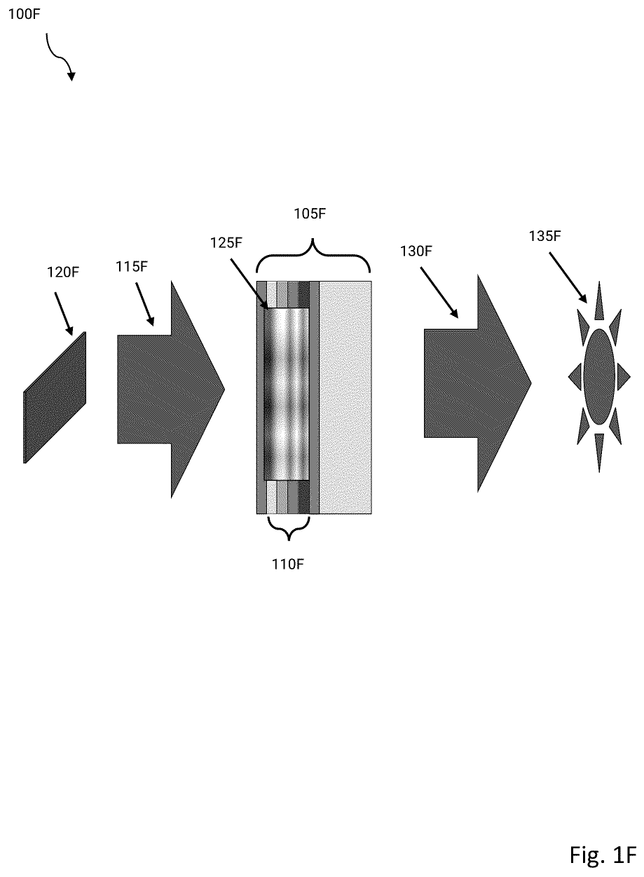

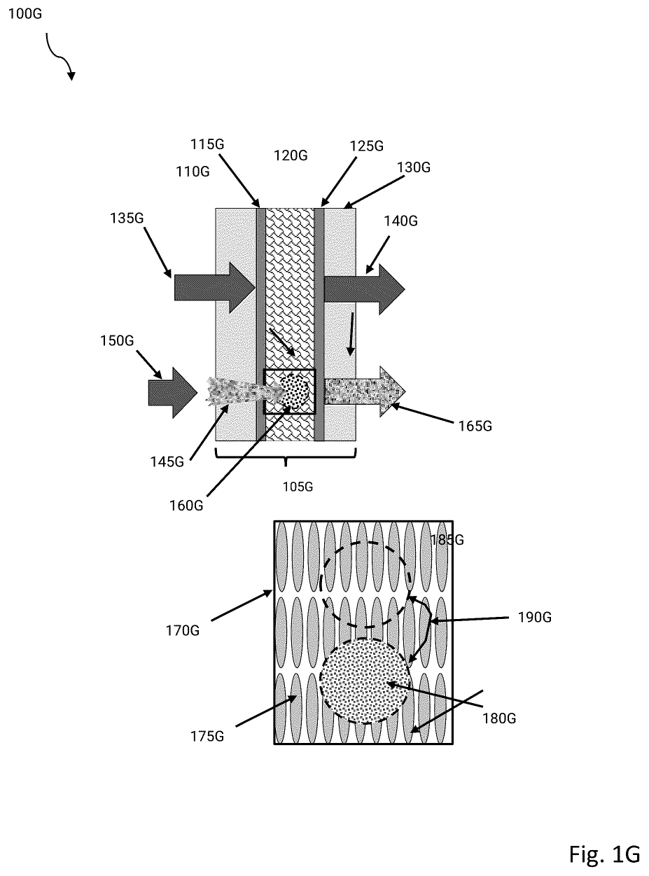

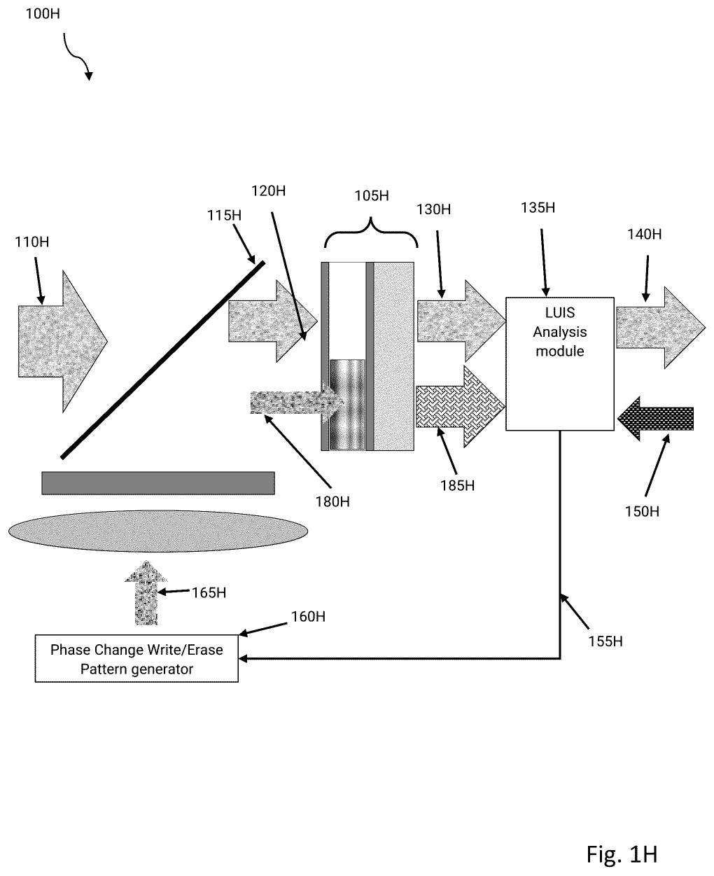

FIG. 1A illustrates a planar phase change light valve system 100A that uses phase change cooling within a light valve structure. An activating material is a thin film volume 135A applied to a supporting substrate. In this arrangement, an unpatterned High Fluence Light (HFL) beam 105A passes through a beam combiner 125A before entering 100A. The HFL operates at wavelength, λ1, at a time with respect to the timing cycle of t1 and a pulse width of τ1. In optical memory applications, the wavelength is typically in the green (532 nm) or blue (450 nm). Pulse widths are typically in the picoseconds (<1 ns, <0.1 Ins, <10 ns, or <100 ns) for the Write beam and 10 to 500 microseconds for the erase beam. A patterned low fluence Write beam 110A reflects off 125A and enters 100A as 115A. The Write beam operates at 22 and becomes activated at t2 and has a pulse width of τ2 and a fluence of E1. Additionally, to write beam 110A, a patterned Erase beam 120A operating at either λ2 or λ3 but being time synched so that it is present only after 110A (if both are operating at λ2) with t3>t2+τ2, a pulse duration of τ3, and a fluence E2. The Erase beam can operate simultaneously with the Write beam in some embodiments by operating at λ3 with the same timing requirements (t3 and τ3) as above. There is an additional requirement for simultaneous operation of the Write and Erase beams (given the thin film nature of the media) is that they cannot operate on the same pixels. Erase beam 120A becomes 130A after being reflected off of beam combiner 125A before entering light valve system 100A.

In one embodiment, a Phase Change LV can be configured so that the Write and Erase beams operate at the same wavelength (λ2). The Write 110A and Erase 120A beams have fluences and pulse widths of E1/E2 and τ2/τ3, respectively, where E1>E2 and τ2<τ3. The Write beam illuminates a phase change LV that contains a thin-film phase change material 135A that can have a thickness between 150 nm to 2 μm thick., For example, in one embodiment a crystalline germanium-antimony-tellurium (Ge₂Sb₂Te₅, also known as GST) film can be used. Such a GST film can sit atop a seed layer 140A composed of an equivalent crystalline structure, such as sodium chloride or NBK7 glass. The Write beam can be activated at t2 and its fluence and wavelength is such that it causes GST film to undergo a phase change from crystalline to amorphous in the areas where the film is illuminated. Write beam 110A's pulse width (τ2) is, in one embodiment, 2-3 picoseconds in pulse duration, and when write beam 110A is switched off, the amorphous volume freezes as amorphous.

The refractive index change can be large when the material goes from crystalline to amorphous. For example, in the case of GST, its crystalline index of refraction is typically 6.5 changing to 3.85 in its amorphous state. Additionally, thin-film phase change material 135A can be birefringent in its crystalline state and homogeneous in its amorphous state. If the LV operates on Total Internal Reflection or other index sensitive means to modify the HFL 105A, then causing thin-film phase change material 135A to drastically change its index in a determined way would allow HFL 105A to have this pattern imposed on it by allowing it to pass through a previously (when thin-film phase change material 135A was crystalline) defined reflective surface. If the LV operates by polarization, then changing thin-film phase change material 135A from a birefringent crystal to homogeneous material switches off the material polarization modifying attribute and HFL 105A would have the Write beam pattern imposed on it.

The Erase beam 120A strikes the written area and due to its fluence, wavelength and pulse width, presents a low power version of the Write beam over a longer time frame. The Erase beam 120A raises the temperature of the amorphous regions of thin-film phase change material 135A to above its glass transition point and holds it there until recrystallization occurs in the affected volumes due to features inherent in the seed layer templates or in neighboring unaffected volumes. The pulse width 13 of Erase beam 120A is typically in the tens of nanoseconds (for GST).

On light valve system 100A, the thin film phase change media 135A can be several different materials including a large number of chalcogenide glasses such as GST, Sc_{0.2}Sb₂Te₃, GeTe, Ag₄In₃Sb₆₇Te₂₆, Ge₁₅Sb₈₅, or Sb. Additionally, polycrystalline materials such as CdTe, AZO, ZnSe, ZnS, or Si can be used. In some case nonlinear aspects of Liquid Crystals can be used in which the non-linearity causes a phase change in the liquid crystals and their arrangements. In addition, quantum dots, artificial dielectrics, or metamaterials composed of the above mentioned groups of discrete materials (chalcogenides, polycrystalline or nonlinear liquid crystals) can be used in thin-film phase change material 135A. This thin layer can be deposited onto a coated supporting substrate 145A or onto an intermediate layer 140A, that can act as a baseline seeding structure, an antireflective stack, a thermal dissipative or insulative layer or a general interface to the supporting substrate to aid adhesion and the film's functionality.

The HFL 105A that enters and interacts with the affected pattern imposed onto thin-film phase change material 135A by the actions of Write Beam 110A leaves light valve system 100A and becomes HFL laser 175A, containing both patterned and unpatterned HFL light. This beam strikes a pattern discriminator 190A which splits the patterned HFL light 180A from the unpatterned light HFL light 185A. The patterned HFL 180A gets imaged to a data storage target while unpatterned HFL light 185A goes into a beam dump or gets reformatted or otherwise processed. The pattern discriminator depends on what attribute is being used to differentiate HFL light 180A from HFL light 185A. In the case of changes to thin-film phase change material 135A's birefringence, then pattern discriminator 190A is polarizing beam splitter; if it is phase, then pattern discriminator 190A could be interference structure or similar coherent structures that can translates phase to amplitude.

Advantageously, as compared to conventional LVs, phase change LVs are composed of materials that have a higher inherent laser damage threshold. Once information is written into Phase Change LVs, the LV interacts with the HFL beam without the HFL affecting the LV's state.

Another embodiment takes advantage of long-term phase change pattern latency. Common patterns that need to be printed in various areas of the data storage target can be written and provide a pseudo static image without the need for additional Write beam 110A or Erase beam 120A light until a change or modification is needed.

FIG. 1B illustrates a volumetric phase change light valve 100B. Unpatterned HFL light 105B operating at λ1 and t1 with a pulse width of t1 passes through the dichroic combiner 110B and becomes HFL light 115B before entering the volumetric Pphase change light valve 116B. Pattern Write/Erase beam 125B, operating at a wavelength of λ1/2 and t1/2 with a pulse width of τ1/2 relative to the HFL passes through imaging lens 120B and phase delay light valve 130B before reflecting off of dichroic combiner 110B to become the Write beam 140B or the Erase beam 150B. The phase change light valve 116B is composed of a top cladding/seed layer 165B, a volumetric phase change material 170B, a bottom cladding/seed layer 175B, and a supporting substrate 180B. A pattern 145B can be written by Write beam 140B while a volumetric pattern 155B can be erased by Erase beam 150B. A previously written pattern 160B acts upon HFL light 115B, resulting in a HFL beam 185B containing both pattern and unpatterned features that passes through a pattern separator 190B. Patterned HFL beam 195B passes through the pattern separator while the unpatterned beam 200B gets diverted to a beam dump or gets reformatted or otherwise processed.

The volumetric phase change material 170B is usually a crystalline material, as described above but could also be amorphous, liquid crystal, glass, ceramic, polymer, quantum dot, artificial dielectric, plasmonic, or metamaterial. The volumetric phase change material should be transparent and non-absorptive at λ1 (HFL wavelength) while being absorptive at λ2 and/or λ3 (write and erase wavelengths). Additionally, the phase change material could be a material that can exhibits a susceptibility non-linearity (χ2 or χ3) so it has no reactivity to λ1 but does have high reactivity to λ2 and/or λ3.

The phase change on exposure to at λ2 and λ3 is such that some aspect of at λ1 light can be be modified, including but not limited to optical phase delay/advancement (delay of the optical wave packet or group velocity), shift in the polarization vector, displacement of the volume's overall spectral response to at λ1, modification of the amplitude/intensity of HFL light 115B, change of the transmissivity or reflectivity of volumetric phase change material 170B with respect to HFL light 115B or a change in the emission angle of HFL beam 185B with respect to incident angle of HFL light 115B.

The phase change within volumetric phase change material 170B can be very localized and discrete as exemplified by previously written pattern 160B with discrete changes voxels or it could be gray scale continuous across the span of volumetric phase change material 170B, depending on the gray scale value of the pattern contained in Write beam 140B and Erase beam 150B. The depth (Δz) at which the writing or erasure takes place depends on the gray scale value imposed onto Write beam 140B/Erase beam 150B by phase delay light valve 130B.

In one embodiment Write beam 140B and Erase beam 150B can operate at λ2 and λ3, respectively; in which case they can operate on volumetric phase change material 170B simultaneously on adjacent voxels. If the desire is to write and erase in the same volume of material, then an additional embodiment would require a second phase delay light valve 130B to act separately on at λ2 and λ3, this embodiment is not shown, but would require additional optical circuits prior to imaging lens 120B.

Erasure of any voxel volume by Erase beam 150B would use either the neighboring unaffected volume or features/structure of top cladding/seed layer 165B and bottom cladding/seed layer 175B to allow the phase change material to return to its native/initial state.

FIG. 1C illustrates a quantum dot phase change light valve 100C. Phase change material 110C can be either a planar structure (capable of taking on one discrete voxel) or volumetric (many discrete voxels in a column, gray scale voxels in the 3D volume, or analog gray scale across 3D volume, collectively depicted as 111C). An unpatterned HFL operating at λ1 is incident on a quantum dot based phase change light valve 105C in the area in which the volume of quantum dots within phase change material 110C have been modified by a patterned light beam 120C beam operating at λ2, I1, t1 with duration τ1 (wavelength, fluence, and time interval, respectively). Patterned light beam 120C enters quantum dot based phase change light valve 105C and acts on phase change material 110C before an unpatterned HFL beam 115C enters this volume. The write beam 120C causes the quantum dots to undergo a phase change so that their optical properties changes with respect to unpatterned HFL beam 115C, enabling phase change material 110C to affect unpatterned HFL beam 115C's amplitude, phase, polarization, or spectral response as it passes through phase change material 110C, thus changing unpatterned HFL beam 115C into patterned HFL beam 130C as it leaves phase change material 110C. The resulting patterned HFL 130C leaves quantum dot based phase change light valve 105C and travels to the data storage target. An unpatterned HFL beam enters into quantum dot based phase change light valve 105C in an area not addressed by patterned light beam 120C and is not affected by the unchanged quantum dots within phase change material 110C, passing through and remaining an unpatterned HFL 135C which travels as waste light and gets transported into a beam dump, an image reformator, or a Switchyard system such as later described in this disclosure.

Phase change material 140C is a close view of phase change material 110C phase change material 140C is composed of quantum dots whose core can be composed of any of the materials mentioned above. The quantum dot is constructed so that its overall dimension is resonant with HFL beam 115C, this resonance is dependent on the optical properties of the core material in either its native state or in its phase changed state. When the core has been modified, then an aspect of its response to HFL beam 115C changes so that affected volume of phase change material 110C will react differently or modify phase change material 110C differently than where it is unaffected by patterned light beam 120C or further modified by the erase beam 150C. The write beam 145C enters phase change material 140C and causes the quantum dots that it illuminates to undergo a phase change. The core of quantum dot is composed of a material that has an absorption at λ2 and λ3 but has no absorption at Al.

Quantum dot 155C can be composed of a core 175C covered with a number of shells with the outermost shell 160C resonant at λ1 and with one or more of the inner shell dimensions being resonant with 22/23. The inner shells contain a buffer layer 165C and a seed layer 170C. There can be more shells than these two mentioned with the added requirement that buffer layer 165C and seed layer 170C are not absorptive at any wavelength. A portion of patterned light beam 120C is incident on phase change material 110C and is shown as write beam 145C being incident on a subsection of phase change material 140C, likewise, a portion 180C of write beam 145C is shown being incident on a single quantum dot. Since an inner shell dimension is resonant at λ2, portion of write beam 180C enters into an outer boundary 160C of quantum dot 155C and undergoes multiple reflections inside the outer boundary 160C with its operating parameters of λ2, I1, and τ1 causing the core to undergo a phase change from (as an example) crystalline to amorphous. This phase change results in an index and/or birefringence modification for HFL beam 115C and a resonance change at λ1. The modification will affect HFL beam 115C as it passes through quantum dot 155C and the ensemble of quantum dots in the voxel of phase change material 140C where patterned light beam 120C activates.-

The erase beam 150C operates at of λ2 or λ3, I2, t2 with a duration of t2 is incident on phase change material 140C and causes the core of the quantum dots to undergo a phase change from (as an example) amorphous back to crystalline state with the aid of the seed shell layer 170C. Examination of the action of the erase beam 195C incident on a previously changed quantum dot 190C. It enters the quantum dot and causes the core 200C to undergo a phase change back to its original state, represented by the path 205C.

Since the volume of the quantum dot is much smaller than an equal volume of free-standing phase change with the quantum dot's seed layer and is also similarly closer to the volume undergoing forward or erasure phase change, this would allow a quantum dot based phase change light valve 105C to activate/erase much faster than a standard volumetric or planar phase change LV.

Another embodiment has one of the shell layers (for instance shell layer 170C) selected to be absorptive at λ1 and the interior of the quantum dot 175C to not be absorptive. Instead, interior of the quantum dot 175C can act as a seed structure for the restoration process during the erase cycle. This would be beneficial for the purpose of decreasing the erasure time as the volume and absorption function can be enhanced through deposition methods. An additional benefit is to increase the number of potential materials that could be used for phase change/reset as the phase change parameters could then be tailored by process instead of dependent on the natural absorption function of bulk materials.

FIG. 1D illustrates metamaterial phase change light valve 100D. Metamaterial structure 110D is the active phase change material in the metamaterial phase change LV structure 105D. A modified volume-based or planar metamaterial phase change material 115D (detail 155D) is shown as planar for clarity. An unpatterned beam 120D enters 105D and interacts with modified volume-based or planar metamaterial phase change material 115D and becomes a patterned HFL beam 130D upon leaving phase change light valve structure 105D wherever the patterned write/erase beam 125D has caused metamaterial structure 110D to undergo a phase change. The unpatterned beam 120D operates at of λ1 at t1 with a duration of τ1, while patterned write/erase beam 125D operates at λ2/λ3, I2/I3, t2/t3 with a duration of τ2/τ3 for the write and erase beam, respectively. In areas not modified by the patterned write/erase beam 125D, an HFL beam 135D would enter 105D and not be affected with its passage through metamaterial structure 110D and would remain an unpatterned HFL beam 140D.

In an example, write beam 145D enters phase change material 141D; this beam typically has a fluence that is short and intense so that (typically) I2>I3 and I2<I3. Write beam 145D is absorbed so that the material 141D undergoes a phase change (as example) from crystalline to amorphous state, this process in τ2 timeframe and the material quickly stabilizes into a new amorphous before it can recrystallizes. The amorphous state causes a change in the meta-material properties and its response to unpatterned beam 120D. This response can be spectral, polarization, or a change of material 141D's complex impedance so that its transmissivity or reflectivity response at λ1 is affected and thus modifying unpatterned beam 120D's amplitude, phase, polarization, or direction up leaving the metamaterial-based phase change light valve 105D. Since write beam 145D performs this modification to material 141D spatially, the outgoing patterned HFL 130D is modified. Write beam 145D can support gray scale and can produce varied levels of polycrystalline state to material 141D from fully crystalline (pixel is not activated) to fully amorphous (pixel is fully activated).

An erase beam 150D enters material 141D and is absorbed so that the material undergoes phase change (as an example) from amorphous to crystalline and returns the metamaterial to its original state. Erase beam 150D can be also patterned and can reset the pixels with equal gray scale level as that afforded by write beam 145D.

Material 141D is also shown as material 155D which shows a small subset of planar metamaterial features. A volume equivalent can be realized of this array by using structured quantum dots in which the complex resonance can be formed using various shell materials and QD shapes (spheres versus ellipsoids versus platelets versus other volumetric shapes). Material 141 D is also shown as material 180D which depicts an array of metamaterial circuits atop a crystalline layer 160D with an example metamaterial circuit 165D is shown. This exemplary metamaterial circuit is composed of features metamaterial structures 170D which resonate at Al and a control structure 175D composed of the same crystalline material as that of crystalline layer 160D. When write beam 145D illuminates material 141D, it is focused at phase change material 175D and causes a phase change of this material so that it changes from crystalline to amorphous. This change causes a change to the resonant structure of metamaterial resonator structures 165D and its response to unpatterned HFL beam 120D, changing it to patterned HFL beam 130D. Likewise when erase beam 150D illuminates material 141D, it is focused at phase change material 175D and can affect those pixels in material 180D that were initially changed by write beam 145D with a lower fluence over a longer pulse duration and in conjunction with the seed layer of crystalline layer 160D, will revert the affected regions that were made amorphous (or various levels of polycrystalline toward amorphous) back to a crystalline (or other levels of polycrystalline towards crystalline). Likewise, with illumination of write beam 145D, erase beam 150D can affect the resonance of material 180D and its response to unpatterned HFL beam 120D but is used to restore the state of material 141D to its initial state. While it was stated that write beam 145D and erase beam 150D operate at λ2/λ3, they could operate at the same wavelength 22; their other parameters (I, t, and t) would most likely be different as these are material dependent.

FIG. 1E illustrates a pixel strained phase change light valve 100E. The phase change material can be crystalline in some embodiments. An unpatterned polarized 110E HFL beam 130E enters pixel strained phase change light valve 105E and passes through a previously patterned voxel array 115E which modifies the polarization state of polarized 110E HFL beam 130E in an image wise fashion to create a patterned HFL beam 120E that contains an elliptical polarization correlated to the created birefringence written into previously patterned voxel array 115E. The action to create this birefringence is produced by creating strain 140 E between voxels 135E in a volumetric patterned image. Shown are two gray scale voxels with each voxel containing a variation in grayscale across any one layer within the voxel. As the material undergoes a differential phase change, strain occurs between the pixels that produces controlled birefringence in this area between pixels. These actions can be performed on either crystalline or amorphous materials. Moving the location of the image laterally in a plane 165E will allow for a two-dimensional (2D) strain image to be generated, doing this for the entire volume will create a three-dimensional (3D) strain field 170E. The strain modifies the refractive index across this narrow region, creating a 2D index grating that when extended to the 3D strain field can produce useful functionality on polarized 110E HFL beam 130E. Since the HFL 130E is a coherent beam, the strain induced index change will cause a differential change in the coherent direction of the output beam of HFL 130E as it interacts and passes through strained voxels 140E to become phase delayed HFL beam 145E with a direction 150E. If the phase change material in pixel strained phase change light valve 105E is initially composed of crystalline material, it would be possible to simultaneously modify its polarization state as well as directional state to be able to produce an amplitude varying spatial image that can be angle manipulated depending on the strain pattern written in the voxels 115E. In the case where HFL 130E is a coherent and polarized incoming beam to pixel strained phase change light valve the pixel-strained voxel is created by overlapping regions 165E in 3D throughout previously patterned voxel array 115E, the resulting 3D strain 170C would encode onto polarized and coherent HFL beam 160E a volumetric phase and amplitude structure and after passing through pixel strained phase change light valve 105E would become complex encoded HFL 175E. The complex encoded HFL 175E would allow single or multiple lobed (180E) output at a distance from 105E, allowing pixel strained phase change light valve 105E to act as a dynamic phase array for a solid-state scanner and or image reformator. The overlapping portion 165E is an extension of what was described with respect to 155E.

FIG. 1F illustrates a structured material strain phase change light valve 100F. In this embodiment, structured materials are used as a replacement for either purely crystalline or amorphous phase change material. Structured materials would include the above set of materials but can be deposited instead of provided by naturally occurring formed layers. In this embodiment the structured material 110F is the phase change volume within a Strain Phase Change LV 105F. An incoming HFL 115F that has a defined shape and may or may not be patterned 120F enters into Strain Phase Change LV 105F and interacts with a previously encoded strain voxel 125F and, upon exiting Strain Phase Change LV 105F, contains this volumetric structure HFL 130F. The voxel information transferred to HFL 115F that is now part of HFL 130F permits the outgoing HFL to be image reformatted to attain an arbitrary profile and different patterning 135F than 120F.

FIG. 1G illustrates a non-linear material phase change light valve system 100G. In this embodiment, materials having non-linear optical or electro-optical characteristics can be modified by write beam operating at λ2 that has no effect at λ1 (at HFL beam operating wavelength). One such material is Liquid Crystal (LC) in Nematic and Isotropic phases. There is a large number of LCs that normally exist in these phases, too numerous to name herein and, which their 3-order susceptibility (χ3) allows them to interact with an write/erase beam in (for example) the blue and UV ranges (and have λ2) their linear electro-optical characteristics be modified for the Near IR (NIR) wavelengths; these materials also have no modifying effects (either linear or non-linear) by the NIR beams. Non-linear material phase change light valve system 100G uses this condition of modification via χ3 process. In a nonlinear activated phase change LV, the LV 105G is composed a top substrate 110G, a top alignment layer 115G which creates an initial pattern by which a volume of LC 120G is oriented to it, a bottom alignment layer 125G which allows a termination alignment arrangement for the LC, and a bottom substrate 130G. An unpatterned HFL beam 135G enters LV 105G in an area not being addressed by a write beam and passes through LV 105G unaffected to become HFL beam 140G; this beam goes into a beam dump or switchyard or otherwise is reformatted. In the areas in which a patterned write beam 145G exists, the LC 120G becomes activated through its χ3 susceptibility and undergoes a phase change 160G between a Nematic (structured) and isotropic (unstructured) phases. This change causes a large change in refractive index of volume of affected LC and allows an incoming unpatterned HFL 150G to become patterned and leave LV 105G as a patterned HLFL beam 165G. An example of the phase change is shown in voxel 170G in which symbolic detail of Nematic LC 185G with the LCs plane aligned with the substrates and each other throughout the volume of liquid crystal 120G. When a patterned femtosecond high repetition rate beam 145G illuminates a volume of LC 120G, the LC undergoes a phase change from nematic 185G to isotropic 180G along path 190G and the refractive index at λ1 is changed allowing an unpatterned HFL 150G to become a patterned HFL 165G. The effect can be very fast, typically <10 us. Once the write beam ceases illumination of this voxel, the neighboring LC molecules cause the affected area to reorganized in a Nematic phase, occurring in 100's of microseconds and much less than 1 ms with the reversion of its refractive index back to the Nematic state, consequently changing isotropic 180G to nematic 185G along with 190G.

FIG. 1H illustrates a use of a phase change light valve in an adaptive optical structure 100H. In this embodiment, a phase change LV is incorporated into a feedback loop by using a LUIS's Analysis module (which include this system's detection module) and LUIS' Image Transfer and Scanning Module, both of which are described in U.S. patent application Ser. No. 17/343,500, which is herein incorporated by reference.

In this arrangement, a phase change light valve 105H is used as a secondary LV in a feedback correction system in a laser system which may or may not include use in AM systems. In this configuration, a patterned HFL beam 110H enters into the Adaptive Optical control loop system 100H by passing through a dichroic beam splitter 115H to become still patterned HFL beam 120H which enters into and through light valve 105H. The phase change LV 105H is initially not activated and no pattern is contained in its phase change volume, thus still patterned HFL 120H passes through phase change light valve 105H and becomes read out beam 130H. This initial (baseline) beam passes through the LUIS' Analysis Module 135H, with a portion of it remaining in to form a reference image, the rest propagating into the LUIS' Image Transfer and scanning assembly 145H. The image transfer assembly 145H transfers read out beam 130H to a destination (this can be an AM bed, or other operational environment) where read out beam 130H interacts with an environment which disturbs and modifies its optical characteristics and which reflects some of this beam back through image transfer assembly 145H to become a distorted version of further read out beam 140H, depicted here as a feedback beam 150H. The feedback beam contains wavefront errors that represent potential print errors, unintentional and unwarranted print errors due to beam issues or optical defects that would corrupt current and future printed areas and which may or may not change rapidly in time (and adaptable to modification via a feedback correction loop). This feedback beam 150H comes back into the LUIS' Analysis Module 135H and gets analyzed with the help of baseline formed from read out beam 130H and forms a wavefront error 155H output from the LUIS' Analysis Module 135H which is fed into the pattern generator 160H which drives phase change light valve 105H. The pattern generator 160H creates a pattern that is imprinted onto a Write/Erase Beam 165H that passes through an imaging lens 170H, through an optical Phase LV 175H and becomes collinear with HFL beam 110H by way of dichroic beam splitter 115H where it modifies phase change light valve 105H via a readout light containing data 180H, creating a correction to patterned HFL 120H which then becomes a corrected HFL beam 185H. The corrected HFL beam 185H undergoes the same process, further refining patterned HFL beam 110H. The correct beam 185H interacts with all the elements and environments downstream which improves the initial aberrations and distortions evident on the initial read out beam 130H so that over time, these aberrations are minimized in real time.

Using the described embodiment of system 100H in additive manufacturing systems allows optical distortion such as linear optical aberrations and local hot/cold spots to be corrected, allowing for better resolved images on the printed part. Systemic fluctuations in melt pool due to localized temperature variations could be reduced so that density and shear pixels stress could be better controlled. Similar issues could be corrected if the patterned HFL beam 110H was part of a weapons-based system with atmospheric and delivered environments had similar aberrations. In general, system 100H can be used in any system in which aberrations exist in transport and end point delivery and which defects reduces the maximal energy/power exchange with the intended surface/volume.

A wide range of lasers of various wavelengths can used in combination with the described phase change light valve system. In some embodiments, possible laser types include, but are not limited to: Gas Lasers, Chemical Lasers, Dye Lasers, Metal Vapor Lasers, Solid State Lasers (e.g. fiber), Semiconductor (e.g. diode) Lasers, Free electron laser, Gas dynamic laser, “Nickel-like” Samarium laser, Raman laser, or Nuclear pumped laser.

A Gas Laser can include lasers such as a Helium-neon laser, Argon laser, Krypton laser, Xenon ion laser, Nitrogen laser, Carbon dioxide laser, Carbon monoxide laser or Excimer laser.

A Chemical laser can include lasers such as a Hydrogen fluoride laser, Deuterium fluoride laser, COIL (Chemical oxygen-iodine laser), or Agil (All gas-phase iodine laser).

A Metal Vapor Laser can include lasers such as a Helium-cadmium (HeCd) metal-vapor laser, Helium-mercury (HeHg) metal-vapor laser, Helium-selenium (HeSe) metal-vapor laser, Helium-silver (HeAg) metal-vapor laser, Strontium Vapor Laser, Non-copper (NcCu) metal-vapor laser, Copper vapor laser, Gold vapor laser, or Manganese (Mn/MnCl₂) vapor laser. Rubidium or other alkali metal vapor lasers can also be used. A Solid State Laser can include lasers such as a Ruby laser, Nd:YAG laser, NdCrYAG laser, Er:YAG laser, Neodymium YLF (Nd:YLF) solid-state laser, Neodymium doped Yttrium orthovanadate (Nd:YVO₄) laser, Neodymium doped yttrium calcium oxoborateNd:YCa₄O(BO₃)₃ or simply Nd:YCOB, Neodymium glass (Nd:Glass) laser, Titanium sapphire (Ti:sapphire) laser, Thulium YAG (Tm:YAG) laser, Ytterbium YAG (Yb:YAG) laser, Ytterbium:2O₃ (glass or ceramics) laser, Ytterbium doped glass laser (rod, plate/chip, and fiber), Holmium YAG (Ho:YAG) laser, Chromium ZnSe (Cr:ZnSe) laser, Cerium doped lithium strontium (or calcium) aluminum fluoride (Ce:LiSAF, Ce:LiCAF), Promethium 147 doped phosphate glass (147Pm⁺³:Glass) solid-state laser, Chromium doped chrysoberyl (alexandrite) laser, Erbium doped anderbium-ytterbium co-doped glass lasers, Trivalent uranium doped calcium fluoride (U:CaF₂) solid-state laser, Divalent samarium doped calcium fluoride (Sm:CaF₂) laser, or F-Center laser.

A Semiconductor Laser can include laser medium types such as GaN, InGaN, AlGaInP, AlGaAs, InGaAsP, GaInP, InGaAs, InGaAsO, GaInAsSb, lead salt, Vertical cavity surface emitting laser (VCSEL), Quantum cascade laser, Hybrid silicon laser, or combinations thereof.

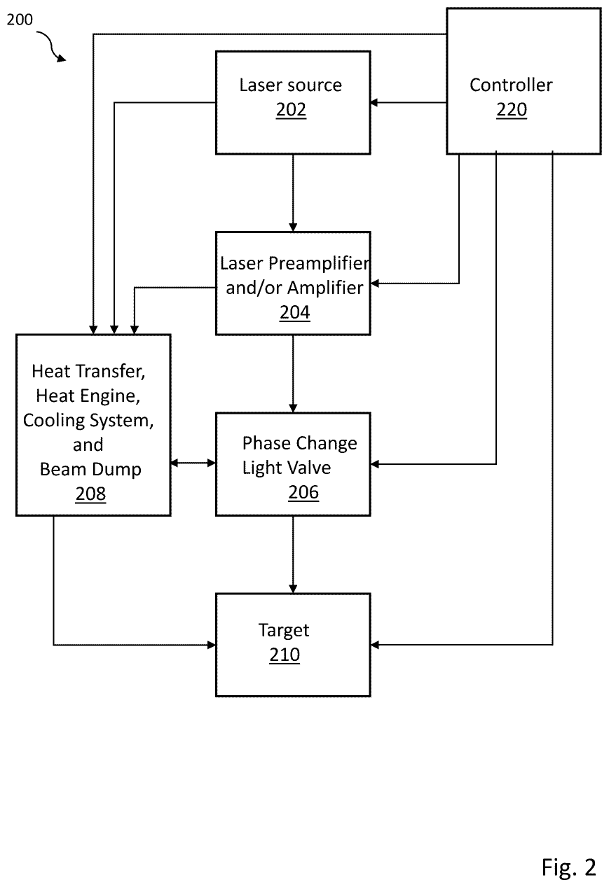

FIG. 2 illustrates use of a phase change light valve such as disclosed herein in a data storage system 200. A laser source 202 directs a laser beam through a laser preamplifier and/or amplifier 204 into a phase change light valve 206. After patterning, light can be directed onto a data storage target 210. In some embodiments, heat or laser energy from laser source 202, laser preamplifier and/or amplifier 204, or an actively cooled light valve 206 can be actively or passively transferred to a heat transfer, heat engine, cooling system, and beam dump 208. Overall operation of the light valve based additive manufacturing system 200 can controlled by one or more controllers 220 that can modify laser power and timing.

In some embodiments, various preamplifiers or amplifiers 204 are optionally used to provide gain to the laser signal, while optical modulators and isolators can be distributed throughout the system to reduce or avoid optical damage, improve signal contrast, and prevent damage to lower energy portions of the system 200. Optical modulators and isolators can include, but are not limited to Pockels cells, Faraday rotators, Faraday isolators, acousto-optic reflectors, or volume Bragg gratings. Pre-amplifier or amplifiers 204 could be diode pumped or flash lamp pumped amplifiers and configured in single and/or multi-pass or cavity type architectures. As will be appreciated, the term pre-amplifier here is used to designate amplifiers which are not limited thermally (i.e. they are smaller) versus laser amplifiers (larger). Amplifiers will typically be positioned to be the final units in a laser system 200 and will be the first modules susceptible to thermal damage, including but not limited to thermal fracture or excessive thermal lensing.

Laser pre-amplifiers can include single pass pre-amplifiers usable in systems not overly concerned with energy efficiency. For more energy efficient systems, multi-pass pre-amplifiers can be configured to extract much of the energy from each pre-amplifier 204 before going to the next stage. The number of pre-amplifiers 204 needed for a particular system is defined by system requirements and the stored energy/gain available in each amplifier module. Multi-pass pre-amplification can be accomplished through angular multiplexing or polarization switching (e.g. using waveplates or Faraday rotators).

Alternatively, pre-amplifiers can include cavity structures with a regenerative amplifier type configuration. While such cavity structures can limit the maximum pulse length due to typical mechanical considerations (length of cavity), in some embodiments “white cell” cavities can be used. A “white cell” is a multi-pass cavity architecture in which a small angular deviation is added to each pass. By providing an entrance and exit pathway, such a cavity can be designed to have extremely large number of passes between entrance and exit allowing for large gain and efficient use of the amplifier. One example of a white cell would be a confocal cavity with beams injected slightly off axis and mirrors tilted such that the reflections create a ring pattern on the mirror after many passes. By adjusting the injection and mirror angles the number of passes can be changed.

Amplifiers are also used to provide enough stored energy to meet system energy requirements, while supporting sufficient thermal management to enable operation at system required repetition rate whether they are diode or flashlamp pumped. Both thermal energy and laser energy generated during operation can be directed for heat transfer, to a heat engine, a cooling system, or a beam dump 208.

Amplifiers can be configured in single and/or multi-pass or cavity type architectures. Amplifiers can include single pass amplifiers usable in systems not overly concerned with energy efficiency. For more energy efficient systems, multi-pass amplifiers can be configured to extract much of the energy from each amplifier before going to the next stage. The number of amplifiers needed for a particular system is defined by system requirements and the stored energy/gain available in each amplifier module. Multipass pre-amplification can be accomplished through angular multiplexing, polarization switching (waveplates, Faraday rotators). Alternatively, amplifiers can include cavity structures with a regenerative amplifier type configuration. As discussed with respect to pre-amplifiers, amplifiers can be used for power amplification.

In some embodiments, thermal energy and laser energy generated during operation of system 200 can be directed into the heat transfer, heat engine, cooling system, and beam dump 208. Alternatively, or in addition, in some embodiments the beam dump 208 can be a part of a heat transfer system to provide useful heat to other industrial processes. In still other embodiments, the heat can be used to power a heat engine suitable for generating mechanical, thermoelectric, or electric power. In some embodiments, waste heat can be used to increase temperature of connected components. As will be appreciated, laser flux and energy can be scaled in this architecture by adding more pre-amplifiers and amplifiers with appropriate thermal management and optical isolation. Adjustments to heat removal characteristics of the cooling system are possible, with increase in pump rate or changing cooling efficiency being used to adjust performance.

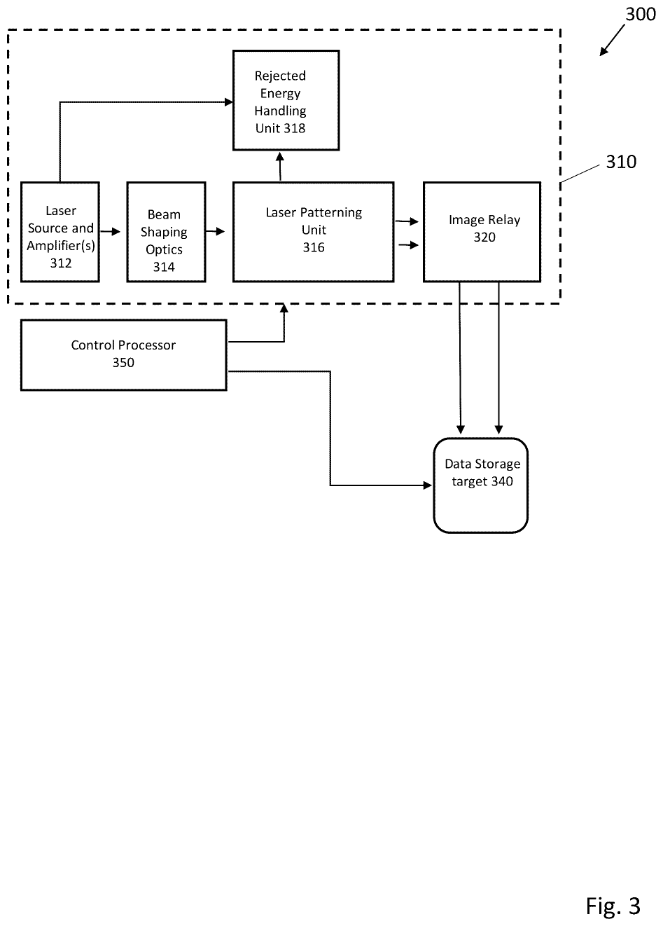

FIG. 3 illustrates a data storage system 300 that can accommodate phase change light valves as described in this disclosure. As seen in FIG. 3, a laser source and amplifier(s) 312 can include phase change light valves and laser amplifiers and other components such as previously described. As illustrated in FIG. 3, the additive manufacturing system 300 uses lasers able to provide one or two dimensional directed energy as part of a laser patterning system 310. In some embodiments, one dimensional patterning can be directed as linear or curved strips, as rastered lines, as spiral lines, or in any other suitable form. Two-dimensional patterning can include separated or overlapping tiles, or images with variations in laser intensity. Two-dimensional image patterns having non-square boundaries can be used, overlapping or interpenetrating images can be used, and images can be provided by two or more energy patterning systems. The laser patterning system 310 uses laser source and amplifier(s) 312 to direct one or more continuous or intermittent energy beam(s) toward beam shaping optics 314. After shaping, if necessary, the beam is patterned by a laser patterning unit 316 that includes either a transmissive or reflective light valve, with generally some energy being directed to a rejected energy handling unit 318.

Patterned energy is relayed by image relay 320 toward a data storage target 340, in one embodiment as a two-dimensional image. Patterned energy, directed by the image relay 320, can melt, fuse, sinter, amalgamate, change crystal structure, influence stress patterns, or otherwise chemically or physically modify the data storage target 340 to form structures with desired properties. A control processor 350 can be connected to variety of sensors, actuators, heating or cooling systems, monitors, and controllers to coordinate operation of the laser source and amplifier(s) 312, beam shaping optics 314, laser patterning unit 316, and image relay 320, as well as any other component of system 300. As will be appreciated, connections can be wired or wireless, continuous or intermittent, and include capability for feedback (for example, thermal heating can be adjusted in response to sensed temperature).

In some embodiments, beam shaping optics 314 can include a great variety of imaging optics to combine, focus, diverge, reflect, refract, homogenize, adjust intensity, adjust frequency, or otherwise shape and direct one or more laser beams received from the laser source and amplifier(s) 312 toward the laser patterning unit 316. In one embodiment, multiple light beams, each having a distinct light wavelength, can be combined using wavelength selective mirrors (e.g. dichroics) or diffractive elements. In other embodiments, multiple beams can be homogenized or combined using multifaceted mirrors, microlenses, and refractive or diffractive optical elements.

Laser patterning unit 316 can include static or dynamic energy patterning elements. For example, laser beams can be blocked by masks with fixed or movable elements. To increase flexibility and ease of image patterning, pixel addressable masking, image generation, or transmission can be used. In some embodiments, the laser patterning unit includes addressable light valves, alone or in conjunction with other patterning mechanisms to provide patterning. The light valves can be transmissive, reflective, or use a combination of transmissive and reflective elements. Patterns can be dynamically modified using electrical or optical addressing. In one embodiment, a transmissive optically addressed light valve acts to rotate polarization of light passing through the valve, with optically addressed pixels forming patterns defined by a light projection source. In another embodiment, a reflective optically addressed light valve includes a write beam for modifying polarization of a read beam. In certain embodiments, non-optically addressed light valves can be used. These can include but are not limited to electrically addressable pixel elements, movable mirror or micro-mirror systems, piezo or micro-actuated optical systems, fixed or movable masks, or shields, or any other conventional system able to provide high intensity light patterning.

Rejected energy handling unit 318 is used to disperse, redirect, or utilize energy not patterned and passed through the image relay 320. In one embodiment, the rejected energy handling unit 318 can include passive or active cooling elements that remove heat from both the laser source, light valve(s), and amplifier(s) 312 and the laser patterning unit 316. In other embodiments, the rejected energy handling unit can include a “beam dump” to absorb and convert to heat any beam energy not used in defining the laser pattern. In still other embodiments, rejected laser beam energy can be recycled using beam shaping optics 314. Alternatively, or in addition, rejected beam energy can be directed to data storage target 340 for further patterning. In certain embodiments, rejected beam energy can be directed to additional data storage targets.

In one embodiment, a “switchyard” style optical system can be used. Switchyard systems are suitable for reducing the light wasted in the additive manufacturing system as caused by rejection of unwanted light due to the pattern to be printed. A switchyard involves redirections of a complex pattern from its generation (in this case, a plane whereupon a spatial pattern is imparted to structured or unstructured beam) to its delivery through a series of switch points. Each switch point can optionally modify the spatial profile of the incident beam. The switchyard optical system may be utilized in, for example and not limited to, laser-based additive manufacturing techniques where a mask is applied to the light. Advantageously, in various embodiments in accordance with the present disclosure, the thrown-away energy may be recycled in either a homogenized form or as a patterned light that is used to maintain high power efficiency or high throughput rates. Moreover, the thrown-away energy can be recycled and reused to increase intensity to print more difficult materials.

Image relay 320 can receive a patterned image (either one or two-dimensional) from the laser patterning unit 316 directly or through a switchyard and guide it toward the article processing unit 340. In a manner similar to beam shaping optics 314, the image relay 320 can include optics to combine, focus, diverge, reflect, refract, adjust intensity, adjust frequency, or otherwise shape and direct the patterned light. Patterned light can be directed using movable mirrors, prisms, diffractive optical elements, or solid state optical systems that do not require substantial physical movement. One of a plurality of lens assemblies can be configured to provide the incident light having the magnification ratio, with the lens assemblies both a first set of optical lenses and a second sets of optical lenses, and with the second sets of optical lenses being swappable from the lens assemblies. Rotations of one or more sets of mirrors mounted on compensating gantries and a final mirror mounted on a build platform gantry can be used to direct the incident light from a precursor mirror onto a desired location. Translational movements of compensating gantries and the build platform gantry are also able to ensure that distance of the incident light from the precursor mirror to data storage target 340 is substantially equivalent to the image distance. In effect, this enables a quick change in the optical beam delivery size and intensity across locations of a build area for different materials while ensuring high availability of the system.

In addition to material handling components, the data storage target 340 can be used in combination with components for holding and supporting 3D structures, mechanisms for heating or cooling the data storage target 340, auxiliary or supporting optics, and sensors and control mechanisms for monitoring or adjusting material or environmental conditions. The data storage target 340 can, in whole or in part, be supported in a vacuum or inert gas atmosphere to reduce unwanted chemical interactions as well as to mitigate the risks of fire or explosion (especially with reactive metals). In some embodiments, various pure or mixtures of other atmospheres can be used, including those containing Ar, He, Ne, Kr, Xe, CO₂, N₂, O₂, SF₆, CH₄, CO, N₂O, C₂H₂, C₂H₄, C₂H₆, C₃H₆, C₃H₈, i-C₄H₁₀, C₄H₁₀, 1-C₄H₈, cic-₂,C₄H₇, 1,3-C₄H₆, 1,2-C₄H₆, C₅H₁₂, n-C₅H₁₂, i-C₅H₁₂, n-C₆H₁₄, C₂H₃C₁, C₇H₁₆, C₈H₁₈, C₁₀H₂₂, C₁H₂₄, C₁₂H₂₆, C₁₃H₂₈, C₁₄H₃₀, C₁₅H₃₂, C₁₆H₃₄, C₆H₆, C₆H₅-CH₃, C₈H₁₀, C₂H₅OH, CH₃OH, iC₄H₈. In some embodiments, refrigerants or large inert molecules (including but not limited to sulfur hexafluoride) can be used. An enclosure atmospheric composition to have at least about 1% He by volume (or number density), along with selected percentages of inert/non-reactive gases can be used.

Control processor 350 can be connected to control any components of data storage system 300 described herein, including lasers, laser amplifiers, optics, heat control, build chambers, and manipulator devices. The control processor 350 can be connected to variety of sensors, actuators, heating or cooling systems, monitors, and controllers to coordinate operation. A wide range of sensors, including imagers, light intensity monitors, thermal, pressure, or gas sensors can be used to provide information used in control or monitoring. The control processor can be a single central controller, or alternatively, can include one or more independent control systems. The controller processor 350 is provided with an interface to allow input of manufacturing instructions. Use of a wide range of sensors allows various feedback control mechanisms that improve quality, manufacturing throughput, and energy efficiency.

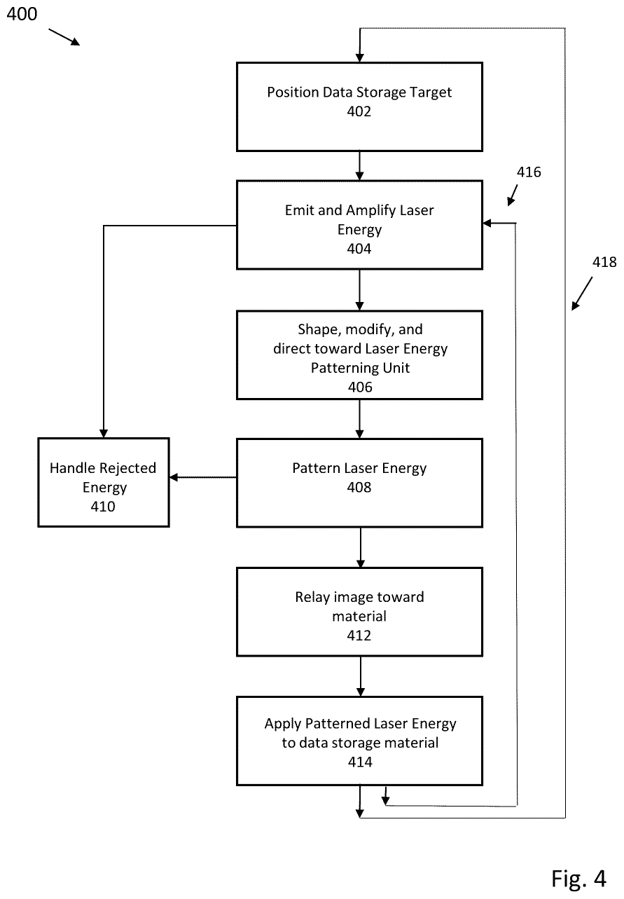

One embodiment of operation of a manufacturing system supporting use of a phase change light valve suitable for additive or subtractive manufacture is illustrated in FIG. 4. In this embodiment, a flow chart 400 illustrates one embodiment of a manufacturing process supported by the described optical and mechanical components. In step 402, a data storage target is positioned in a bed, chamber, or other suitable support.

In step 404, unpatterned laser energy is emitted by one or more energy emitters, including but not limited to solid state or semiconductor lasers, and then amplified by one or more laser amplifiers. In step 406, the unpatterned laser energy is shaped and modified (e.g. intensity modulated or focused). In step 408, this unpatterned laser energy is patterned by a phase change light valve, with energy not forming a part of the pattern being handled in step 410 (this can include use of a beam dump as disclosed with respect to FIG. 2 and FIG. 3 that provide conversion to waste heat, recycling as patterned or unpatterned energy, or waste heat generated by cooling the laser amplifiers in step 404). In step 412, the patterned energy, now forming a one or two-dimensional image is relayed toward the material. In step 414, the image is applied to the data storage target material.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A data storage system, comprising:
a high power laser able to form a laser beam at a first wavelength;
a second laser able to form a write laser beam at a second wavelength;
a 2D patternable light valve having a phase change material responsive to the write laser beam at the second wavelength, and non-responsive at the first wavelength.

2. The data storage system of claim 1, wherein the phase change material supports volumetric phase change.

3. The data storage system of claim 1, wherein the phase change material supports volumetric phase change.

4. The data storage system of claim 1, wherein the phase change material is a quantum dot phase change material.

5. The data storage system of claim 1, wherein the phase change material is a pixel strained phase change material.

6. The data storage system of claim 1, wherein the phase change material is a structured material.

7. The data storage system of claim 1, wherein the phase change material is a non-linear material phase change material.

8. A method of storing data, comprising:
generating a laser beam at a first wavelength;
using a second laser able to form a write laser beam at a second wavelength; and
writing on a phase change material responsive to a write beam at a second wavelength, and non-responsive at the first wavelength, using the write laser beam from second laser to pattern a 2D patternable light valve.

9. The method of storing data of claim 8, wherein the phase change material supports volumetric phase change.

10. The method of storing data of claim 8, wherein the phase change material supports volumetric phase change.

11. The method of storing data of claim 8, wherein the phase change material is a quantum dot phase change material.

12. The method of storing data of claim 8, wherein the phase change material is a pixel strained phase change material.

13. The method of storing data of claim 8, wherein the phase change material is a structured material.

14. The method of storing data of claim 8, wherein the phase change material is a non-linear material phase change material.
